(19) United States
(12) Patent Application Publication
(10) Pub. No.: US 2014/0168910 A1
(43) Pub. Date: Jun. 19, 2014

(54) MOUNTING DEVICE FOR EXPANSION CARD

(71) Applicants: HONG FU JIN PRECISION INDUSTRY (ShenZhen)CO., LTD., (US); HON HAI PRECISION INDUSTRY CO., LTD., New Taipei (TW)

(72) Inventors: XIAO-GANG YIN, Shenzhen (CN); JUN-HUI WANG, Shenzhen (CN)

(73) Assignees: HON HAI PRECISION INDUSTRY CO., LTD., New Taipei (TW); HONG FU JIN PRECISION INDUSTRY (ShenZhen) CO. LTD., Shenzhen (CN)

(21) Appl. No.: 13/723,219

(22) Filed: Dec. 21, 2012

(30) Foreign Application Priority Data
Dec. 14, 2012 (CN) 201210541703.6

(51) Int. Cl. H05K 7/14; H01L 21/68

(52) U.S. Cl. CPC H05K 7/1461; H01L 21/68
USPC 361/747; 29/281.6; 29/729

(57) ABSTRACT

A mounting device for positioning an expansion card includes a positioning apparatus and a slide apparatus. The positioning apparatus includes a positioning case. The positioning case includes a connecting plate and an installing plate extending out from an end of the connecting plate. The slide apparatus includes a slide case slidably connected to the connecting plate and a latching member. The slide case includes a positioning portion facing the installing plate. The latching member is mounted to the positioning portion. The latching member defines a latching slot facing the installing plate. A first end of the expansion card is installed to the installing plate. The slide case is slid relative to the positioning case, until a second end of the expansion card is inserted into and held by the latching slot.

### BACKGROUND

1. Technical Field

The present disclosure relates to a device for mounting an expansion card.

2. Description of Related Art

In installing an expansion card, one end of the expansion card is generally fixed to a chassis, while an opposite end of the expansion cards is cantilevered. As a result, when an expansion card is long and horizontally fixed to the chassis, the cantilevered end may droop and cause damage to the expansion card.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting device with an expansion card; wherein the mounting device includes a positioning apparatus and a slide apparatus.

FIG. 2 is an exploded isometric view of the positioning apparatus of FIG. 1, but viewed from another perspective.

FIG. 3 is an exploded, isometric view of the slide apparatus of FIG. 1.

FIG. 4 is an inverted view of the slide apparatus of FIG. 3.

FIG. 5 is an assembled, isometric view of the mounting device of FIG. 1.

FIG. 6 is an assembled, isometric view of the mounting device of FIG. 1.

FIG. 7 is similar to FIG. 6, but showing the mounting device in another state of use.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

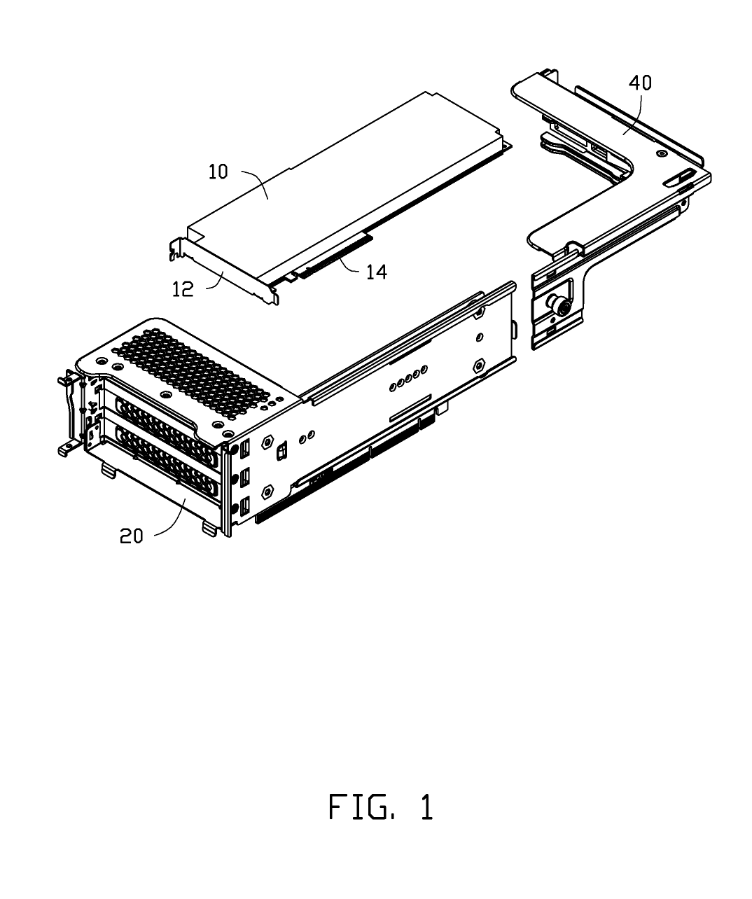

FIG. 1 shows an exemplary embodiment of a mounting device for mounting expansion cards 10 with different lengths. The mounting device includes a positioning apparatus 20 and a slide apparatus 40.

An L-shaped fixing piece 12 is fixed to a first end of the expansion card 10. An edge connector 14 extends out from a side of the expansion card 10.

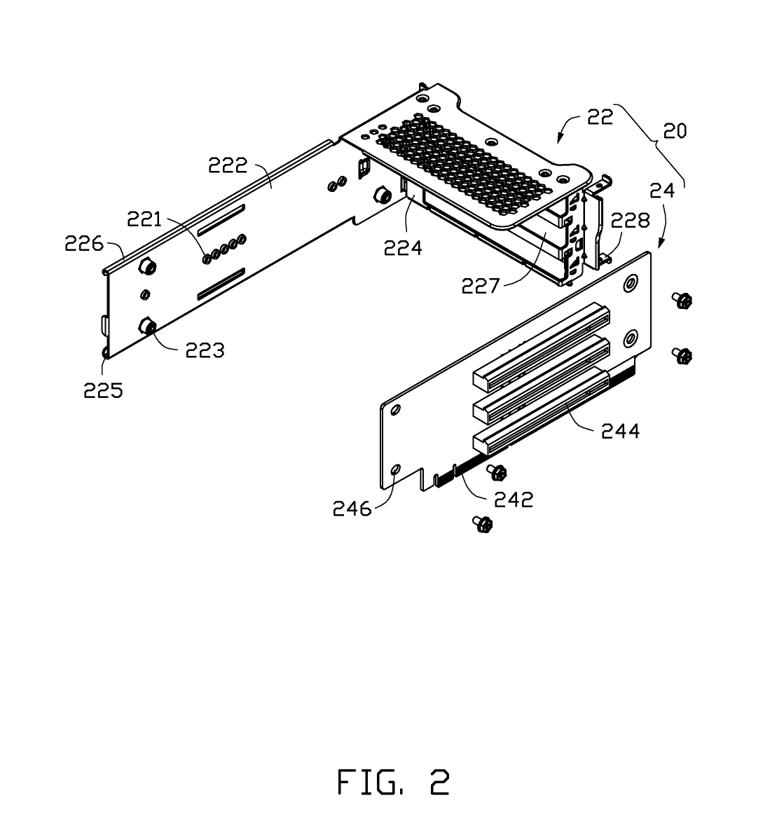

FIG. 2 shows the positioning apparatus 20 including a substantially L-shaped positioning case 22, and an adapter card 24.

The positioning case 22 includes a rectangular connecting plate 222 and an installing plate 224 perpendicularly extending out from an end of the connecting plate 222. A middle of the connecting plate 222 defines a plurality of positioning holes 221 arranged lengthwise along the connecting plate 222. A plurality of supporting poles 223 perpendicularly protrude from four corners of the connecting plate 222. Each supporting pole 223 axially defines a screw hole (not labeled). Two L-shaped extending portions 226 protrude out from opposite sides of the connecting plate 222. Each extending portion 226 and the connecting plate 222 cooperatively bound a slide slot 225 extending lengthwise along the connecting plate 222. The installing plate 224 defines a plurality of installing slots 227 extending along a direction perpendicular to the connecting plate 222. A plurality of latching pieces 228 extends out from the installing plate 228, for latching the positioning apparatus 20 in an enclosure of a server (not shown).

An edge connector 242 extends down from a bottom side of the adapter card 24. A plurality of sockets 244 are formed on a side surface of the adapter card 24. The adapter card 24 defines a plurality of through holes 246 in four corners of the adapter card 24.

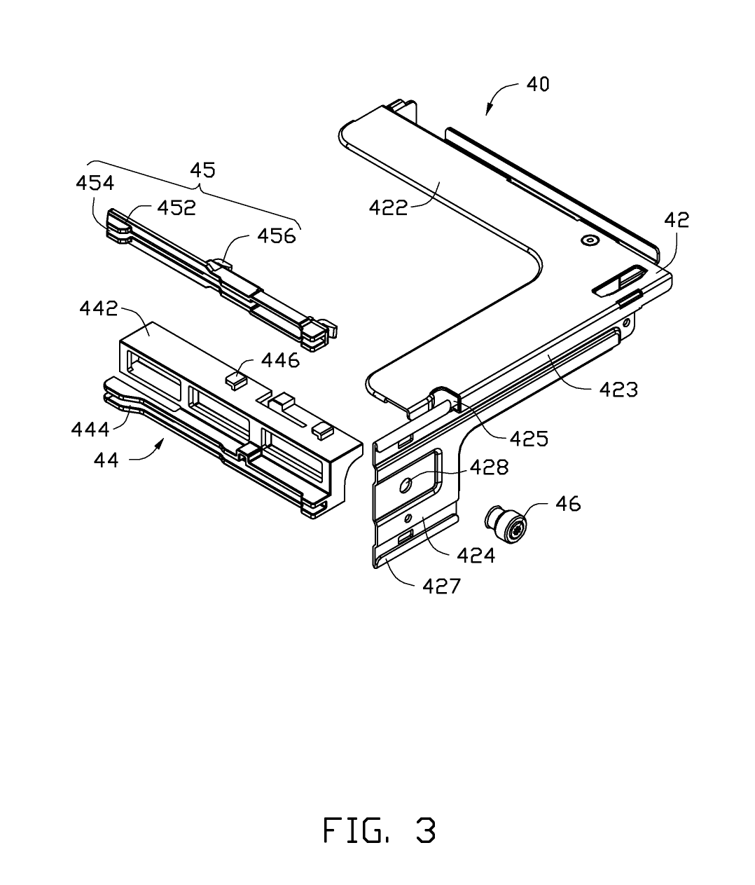

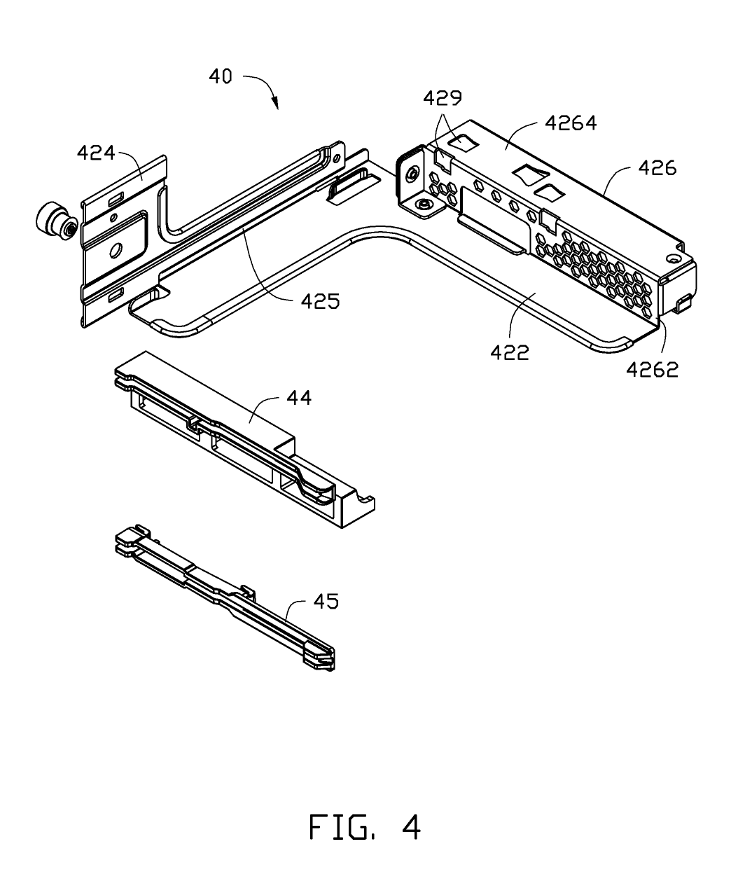

FIG. 3 and FIG. 4 show the slide apparatus 40 including a substantially L-shaped slide case 42, a first latching member 44, a second latching member 45, and a fastener 46.

The slide case 42 includes a substantially L-shaped top plate 422, a slide plate 424 extending down from a first outer side of the top plate 422, a positioning portion 426 protruding from a second outer side of the top plate 422, and an L-shaped connecting portion 423 connected between the top plate 422 and the slide plate 424. The top plate 422 and the connecting portion 423 cooperatively bound a guiding slot 425 extending along the first outer side of the top plate 422. Two slide bars 427 are formed on top and bottom sides of an outer surface of the slide plate 424, extending along a direction perpendicular to the extending direction of the guiding slot 425. The slide plate 424 defines a through hole 428 between the slide bars 427. The positioning portion 426 includes a first latching plate 4262 perpendicularly extending down from the second outer side of the top plate 422, and a second latching plate 4264 perpendicularly extending from a bottom side of the first latching plate 4262 away from the slide plate 424. The first and second latching plates 4262 and 4264 each define a plurality of latching holes 429.

The first latching member 44 includes a bar-shaped main body 442 and a plurality of hooks 446 protruding from a top of the main body 442. A lower portion of a front side of the main body 442 defines a latching slot 444.

The second latching member 45 includes a bar-shaped main body 452 and a plurality of hooks 456 protruding from a rear side of the main body 442. A front side of the main body 452 defines a latching slot 454.

In the embodiment, the fastener 46 is a captive screw.

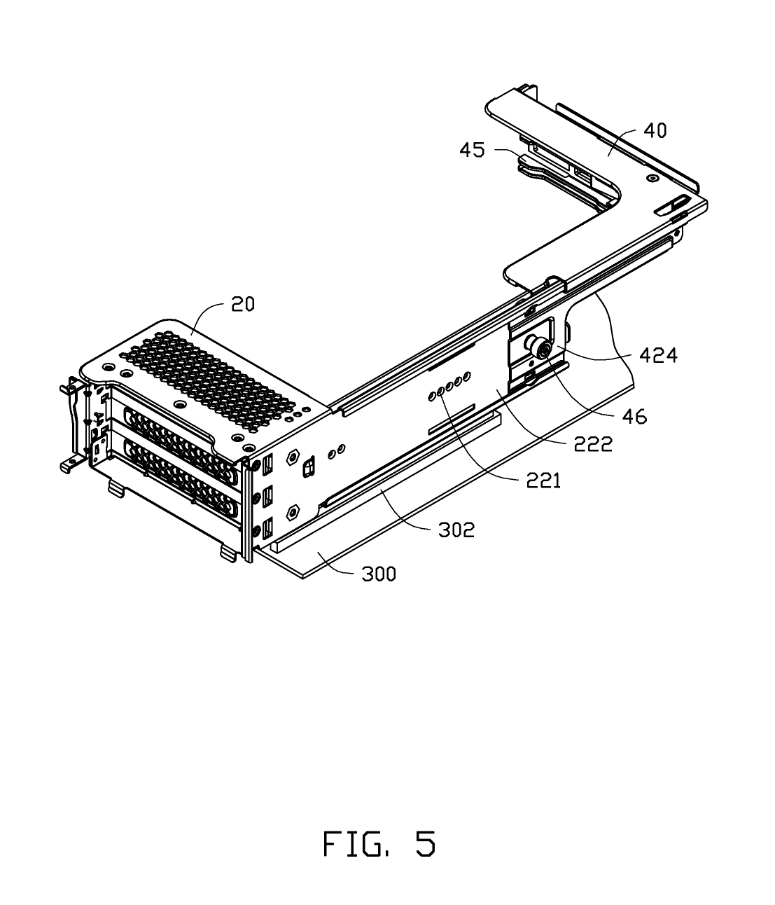

FIG. 5 shows assembly of the mounting device. The latching pieces 228 are mounted on a rear wall (not shown) of the enclosure of the server. The edge connector 242 of the adapter card 24 is inserted into a socket 302 mounted on a motherboard 300 of the enclosure. The supporting poles 223 are inserted into the through holes 246 of the adapter card 24. A screw extends through each through hole 246, to be screwed into one of the screw holes of the supporting poles 223. Thereby, the positioning case 22 is installed in the enclosure, and the adapter card 24 is installed in the positioning case 22 and electrically connected to the motherboard 300.

The hooks 446 of the first latching member 44 are inserted into the latching holes 429 of the second latching plate 4264 from a bottom of the second latching plate 4264, to allow the latching slot 444 to face and be perpendicular to the slide plate 424. The hooks 456 of the second latching member 45 are inserted into the latching holes 429 of the first latching plate 4262 from an inner side of the first latching plate 4262, to allow the latching slot 454 to face and be perpendicular to the slide plate 424.

The slide bars 427 of the slide plate 424 are slidably inserted into the slide slots 225 of the connecting plate 222, and the latching slots 444 and 454 face the installing plate 224 of the positioning case 22. The extending portion 226 at the top side of the connecting plate 222 is slidably inserted into the guiding slot 425 of the slide case 42, until the through hole 428 of the slide plate 424 aligns with one of the positioning holes 221. The fastener 46 extends through the through hole 428, to be screwed into the positioning hole 221.

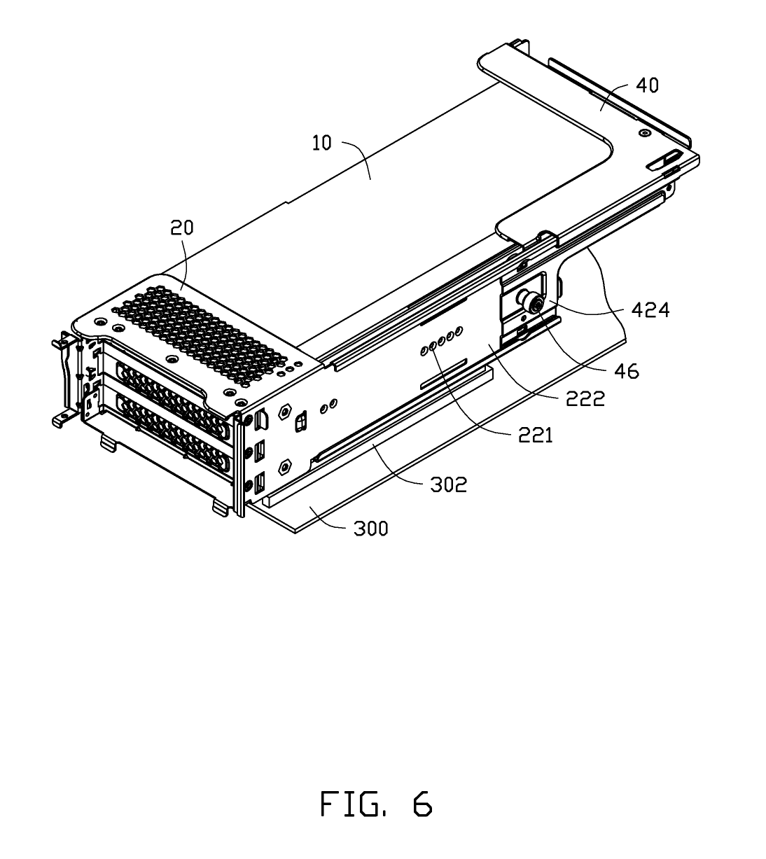

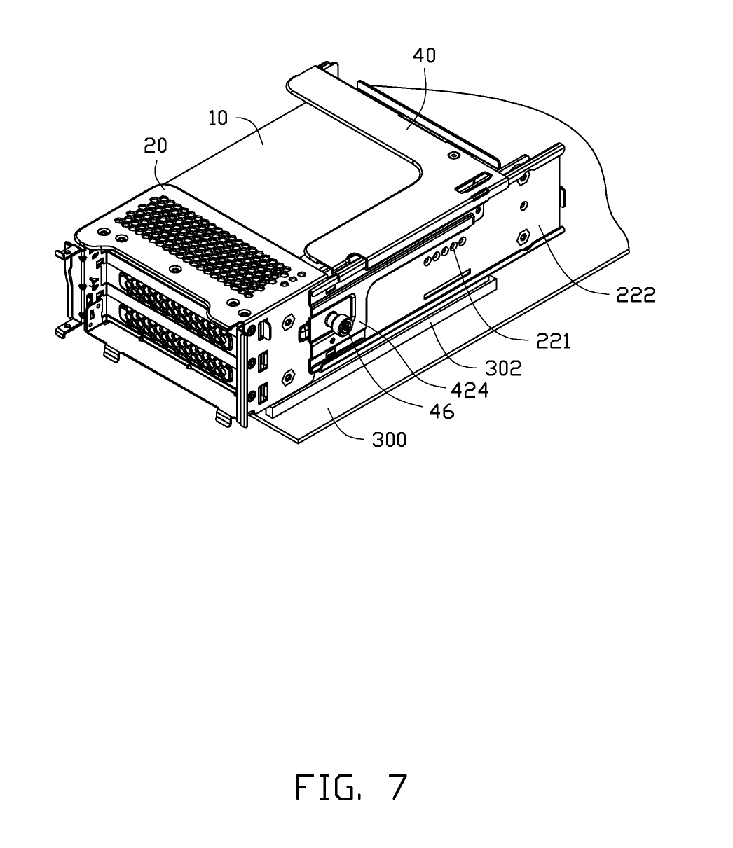

Referring to FIG. 6 and FIG. 7, in use, the fastener 46 is released, and detached from the positioning hole 221. The slide apparatus 40 is slid along the connecting plate 222, and the first and second latching members 44 and 45 move away from the positioning apparatus 20. The fixing piece 12 is fixed in one of the installing slots 227 of the positioning apparatus 20. The edge connector 14 of the expansion card 10 is inserted into one of the sockets 244 of the adapter card 24. The slide apparatus 40 is slid toward the expansion card 10 along the connecting plate 222, until a second end of the expansion card 10 opposite the fixing piece 12 is inserted into the latching slot 444 or 454. The fastener 46 is fastened in the positioning hole 221 again, thereby fixing and providing permanent support to the second end of the expansion card 10. Because a distance between the installing plate 224 and the first and second latching members 44 and 45 can be adjusted along the connecting plate 222, the mounting device has the capability of mounting many expansion cards 10, all with different lengths.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for mounting an expansion card, the mounting device comprising:
a positioning apparatus comprising a positioning case, wherein the positioning case comprises a connecting plate and an installing plate extending out from an end of the connecting plate; and
a slide apparatus comprising a slide case slidably connected to the connecting plate in a direction perpendicular to the installing plate, and a latching member;
wherein the slide case comprises a positioning portion facing the installing plate, the latching member is mounted to the positioning portion, the latching member defines a latching slot facing the installing plate; when mounting the expansion card, a first end of the expansion card is installed to the installing plate, the slide case is slid relative to the positioning case, until a second end of the expansion card is inserted into the latching slot.

2. The mounting device of claim 1, wherein the slide case further comprises a slide plate perpendicular to the positioning portion and slidably connected to the connecting plate, the latching slot of the latching member is perpendicular to the slide plate.

3. The mounting device of claim 2, wherein the connecting plate defines a plurality of positioning holes arranged along a lengthwise direction of the connecting plate, the slide plate defines a through hole, a fastener extends through the through hole of the slide plate, to be fastened into one of the positioning holes of the connecting plate.

4. The mounting device of claim 2, wherein two opposite sides of the connecting plate define two slide slots extending along a lengthwise direction of the connecting plate, two slide bars are formed on two opposite sides of the slide plate extending along a lengthwise direction of the slide plate, the slide bars are slidably inserted into the slide slots, respectively.

5. The mounting device of claim 4, wherein two substantially L-shaped extending portions protrude out from the sides of the connecting plate, each extending portion and the connecting plate cooperatively bound the slide slot.

6. The mounting device of claim 5, wherein the slide case further comprises a top plate connected to the slide plate and the positioning portion, and a substantially L-shaped connecting portion connected between the top plate and the slide plate, the top plate and the connecting portion cooperatively bound a guiding slot extending along the lengthwise direction of the slide plate, the extending portion above the connecting plate is slidably inserted into the guiding slot.

7. The mounting device of claim 6, wherein the positioning portion comprises a first latching plate perpendicularly extending down from the top plate, and a second latching plate perpendicularly extending out from a bottom side of the first latching plate, the first and second latching plates respectively define a plurality of latching holes.

8. The mounting device of claim 7, wherein the latching member comprises a bar-shaped main body and a plurality of hooks protruding out from a rear side of the main body, the plurality of hooks is latched into the corresponding latching holes of the first latching plate, the latching slot is defined in a front side of the main body.

9. The mounting device of claim 7, wherein the latching member comprises a bar-shaped main body and a plurality of hooks protruding up from a top of the main body, the plurality of hooks is latched into the corresponding latching holes of the second latching plate, the latching slot is defined in a front side of the main body.

10. The mounting device of claim 1, wherein the positioning apparatus further comprises an adapter card installed to the connecting plate, the adapter card comprises a first edge connector inserted into a first socket of a motherboard, and a second socket formed on a side surface of the adapter card for receiving a second edge connector of the expansion card.

11. An expansion card module, comprising:
a positioning apparatus comprising a positioning case and an adapter card, wherein the positioning case comprises a connecting plate and an installing plate extending out from an end of the connecting plate, the adapter card comprises a first edge connector inserted into a first socket of a motherboard, and a second socket, and the adapter card is mounted to the connecting plate;
a slide apparatus comprising a slide case slidably connected to the connecting plate in a direction perpendicular to the installing plate, and a latching member; and
an expansion card comprising a second edge connector inserted into the second socket of the adapter card;
wherein the slide case comprises a positioning portion facing the installing plate, the latching member is mounted to the positioning portion, the latching member defines a latching slot facing the installing plate; when mounting the expansion card, a first end of the expansion card is installed to the installing plate, the slide case is slid relative to the positioning case, until a second end of the expansion card is inserted into the latching slot.

12. The expansion card module of claim 11, wherein the slide case further comprises a slide plate perpendicular to the positioning portion and slidably connected to the connecting plate, the latching slot of the latching member is perpendicular to the slide plate.

13. The expansion card module of claim 12, wherein the connecting plate defines a plurality of positioning holes arranged along a lengthwise direction of the connecting plate, the slide plate defines a through hole, a fastener extends through the through hole of the slide plate, to be fastened into one of the positioning holes of the connecting plate.

14. The expansion card module of claim 12, wherein two opposite sides of the connecting plate define two slide slots extending along a lengthwise direction of the connecting plate, two slide bars are formed on two opposite sides of the slide plate extending along a lengthwise direction of the slide plate, the slide bars are slidably inserted into the slide slots, respectively.

15. The expansion card module of claim 14, wherein two substantially L-shaped extending portions protrude out from the sides of the connecting plate, each extending portion and the connecting plate cooperatively bound the slide slot.

16. The expansion card module of claim 15, wherein the slide case further comprises a top plate connected to the slide plate and the positioning portion, and a substantially L-shaped connecting portion connected between the top plate and the slide plate, the top plate and the connecting portion cooperatively bound a guiding slot extending along the lengthwise direction of the slide plate, the extending portion above the connecting plate is slidably inserted into the guiding slot.
